(19) United States
(12) Patent Application Publication
(10) Pub. No.: US 2007/0076396 A1
(43) Pub. Date: Apr. 5, 2007

(54) Plasma display apparatus

(76) Inventor: Yeung Ki Kim, Yongin-si (KR)

Correspondence Address: KNOBBE MARTENS OLSON & BEAR LLP, 2040 MAIN STREET, FOURTEENTH FLOOR, IRVINE, CA, 92614, US

(21) Appl. No.: 11/504,135

(22) Filed: Aug. 11, 2006

(30) Foreign Application Priority Data
Aug. 17, 2005 (KR) 10-2005-0075164

(51) Int. Cl. H05K 7/14; H05K 7/18

(52) U.S. Cl. 361/796

(57) ABSTRACT

A plasma display apparatus having a chassis made of i) nonconductive material such as synthetic resin, and ii) metal is disclosed. In one embodiment, the chassis base has a grounding member included in the chassis base during the injection molding of the chassis base, and bosses are integrated with the chassis base so that a circuit board is fixed to the bosses by bolts. The grounding member, formed of, e.g., metal, grounds the circuit board through bolts which fix the circuit board to the bosses.

### CROSS REFERENCE TO RELATED APPLICATION

This application claims priority to and the benefit of Korean Patent Application No. 2005-0075164, filed Aug. 17, 2005 in the Korean Intellectual Property Office, the entire content of which is incorporated herein by reference.

This application also relates to U.S. patent application (Attorney Docket Number: SDIYPL.062AUS) entitled “Plasma display device,” filed on Jan. 24, 2006, which is incorporated by reference.

### BACKGROUND OF THE INVENTION

1. Field of the invention

The present invention relates to a plasma display apparatus, and more particularly to a plasma display apparatus which has a chassis base made of synthetic resin, thereby easily grounding circuit boards mounted on the chassis base.

2. Description of the Prior Art

In general, a plasma display apparatus refers to a flat display device which uses a plasma display panel so as to display images. The plasma display apparatus includes two substrates having discharging electrodes on opposed faces thereof respectively, and discharging gases injected into closed discharging spaces between the substrates. When a predetermined amount of voltage is applied to the discharging electrodes, ultra-violet radiation is generated in the discharging spaces and excites fluorescent substance so that the fluorescent substance emits light. Thus, the plasma display apparatus can display images using the light emitted from the fluorescent substance.

Typically, the chassis base of a plasma display apparatus is made of aluminum. Recently, it is considered to make a chassis base from a steel plate having strength higher than that of the aluminum, in order to reduce a thickness of the plasma display apparatus.

When the chassis base is made of the steel plate, the chassis base can be thinner than that of the chassis base made of aluminum.

However, when the chassis base is made of aluminum or steel as described above, there are disadvantages in that the total weight of the plasma display apparatus increases due to a weight of the metal material and that the manufacturing cost of the plasma display apparatus increases.

Therefore, the use of synthetic resin for a chassis base has been proposed in order to reduce the weight of the chassis base.

However, although the chassis base made of the synthetic resin has an excellent insulation characteristic, the chassis base cannot ground circuit boards mounted on a rear surface of the chassis base, thus making it difficult to operate a plasma display panel.

### SUMMARY OF THE INVENTION

One aspect of the present invention provides a plasma display apparatus which has a chassis base made of synthetic resin and involving a grounding member made of metal material and inserted in the chassis base, thereby grounding a circuit board.

Another aspect of the invention provides a plasma display apparatus which comprises: a plasma display panel including a front panel and a rear panel, a driving circuit portion including a plurality of circuit boards which are mounted behind the rear surface of the plasma display panel, and a chassis base which includes a body made of synthetic resin and a grounding member disposed in the body to ground the circuit board, and is placed between and coupled to the plasma display panel and the driving circuit portion, the chassis base having bosses integrated therewith, on which the circuit board is mounted.

In one embodiment, the body of the chassis base is formed of synthetic resin which is selected from at least one of the following: polyester resin, polycarbonate resin, and epoxy resin. In one embodiment, the bosses, to which the circuit board is fixed, have a trapezoid or inverted U shaped section and protrude from a rear surface of the chassis base. In one embodiment, the grounding member is made of copper or aluminum and is in electric contact with the circuit board, so as to ground the circuit board.

Another aspect of the invention provides a plasma display apparatus, comprising: a chassis base, having two opposing surfaces, configured to support a plasma display panel in one surface and a plurality of circuit boards located on the other surface of the chassis base and configured to drive the plasma display panel, wherein the chassis base includes i) a body formed from a non-conductive material and ii) a grounding member formed from a conductive material and configured to ground at least one of the plurality of circuit boards, and wherein the body encloses the grounding member.

Sill another aspect of the invention provides a plasma display apparatus, comprising: a chassis base, having two opposing surfaces, configured to support a plasma display panel in one surface and at least one circuit board in the other surface, wherein the chassis base includes i) a body formed from synthetic resin and ii) a grounding member formed from metal and configured to ground the at least one circuit board, and wherein the body encloses the grounding member.

### BRIEF DESCRIPTION OF THE DRAWINGS

Embodiments of the invention will be described with reference to the accompanying drawings.

FIG. 1 is a perspective view showing a plasma display apparatus according to one embodiment of the present invention.

FIG. 2 is a sectional view showing the plasma display apparatus according to one embodiment of present invention, taken along a line II-II in FIG. 1.

FIG. 3 is a sectional view showing a chassis base of the plasma display apparatus according to an embodiment of the present invention.

FIG. 4A is an enlarged sectional view showing the chassis base of the plasma display apparatus according to one embodiment of the present invention, marked with dotted circle A in FIG. 3.

FIG. 4B is an enlarged sectional view showing a chassis base of the plasma display apparatus according to another embodiment of the present invention, in which a portion corresponds to that marked with the dotted circle A in FIG. 3.

FIGS. 5 and 6 are schematic views showing grounding members of the plasma display apparatus according to another embodiment of the present invention.

### DETAILED DESCRIPTION OF THE PREFERRED EMBODIMENTS

Hereinafter, embodiments of the present invention will be described in detail with reference to the accompanying drawings.

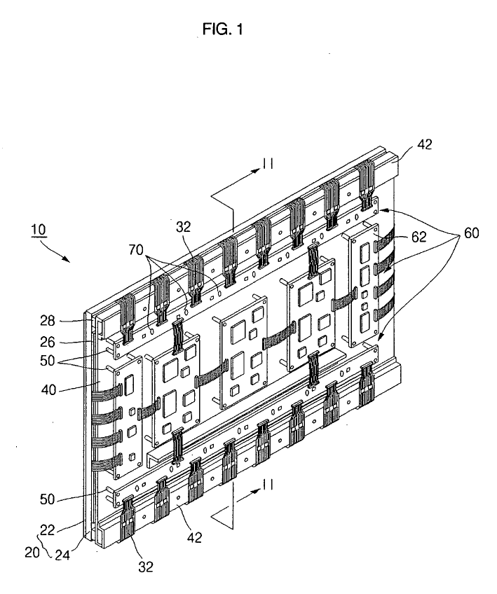

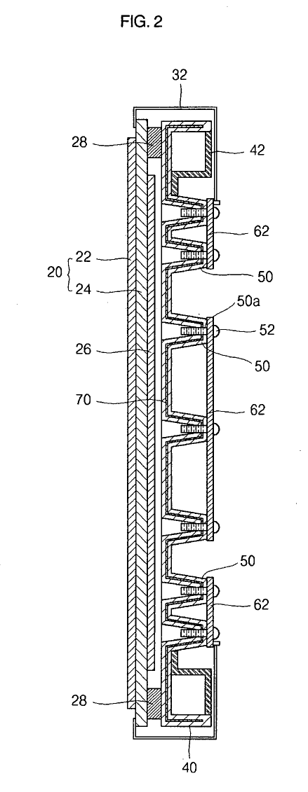

FIG. 1 is a perspective view showing a plasma display apparatus according to one embodiment of the present invention, and FIG. 2 is a sectional view showing the plasma display apparatus according to one embodiment of present invention, taken along a line II-II in FIG. 1. In one embodiment, the plasma display apparatus 10 includes a plasma display panel 20, a chassis base 40 attached to and supported by the plasma display panel 20, and a driving circuit portion 60 having circuit boards 62 mounted on a rear surface of the chassis base 40 opposing the surface facing the plasma display panel 20.

The plasma display panel 20 generally includes a front panel 22 and a rear panel 24, in which voltage applied to electrodes formed in the plasma display panel 20 causes gases filled between the front and rear panels 22 and 24 to generate ultra-violet radiation which then excites a fluorescent substance layer so as to emit visible light. As a result, the plasma display apparatus can display images.

The plasma display apparatus further includes i) discharging cells (not shown) defined by the front panel 22, the rear panel 24, and barrier ribs (not shown), ii) the discharging gases (not shown) which are filled in the discharging cells, iii) the fluorescent substance layer (not shown) coated on a surface of each discharging cell, and iv) electrodes (not shown) subjected to the voltage. Voltages of direct or alternating current applied to the electrodes cause the discharge gases to emit the ultra-violet radiation so as to display the images.

In one embodiment, the plasma display panel 20 adheres to the front surface of the chassis base 40 by an adhesive member 28 such as a double-sided adhesive tape. A heat discharging plate 26 may be provided in an area to which the adhesive member 28 is not attached between the plasma display panel 20 and the chassis base 40. The heat discharging plate 26 adheres to the rear surface of the plasma display panel 20. In one embodiment, the heat discharging plate 26 is spaced from the chassis base 40. The plasma display apparatus generally includes a signal transmitting member 32 and a reinforcing member 42. The signal transmitting member 32 transmits an electrical signal generated at the circuit boards 62 to the plasma display panel 20. In one embodiment, the signal transmitting member 32 includes a flexible printed cable (FPC), a tape carrier package (TCP), or a chip on film (COF). The reinforcing member 42 reinforces the strength of the chassis base 40.

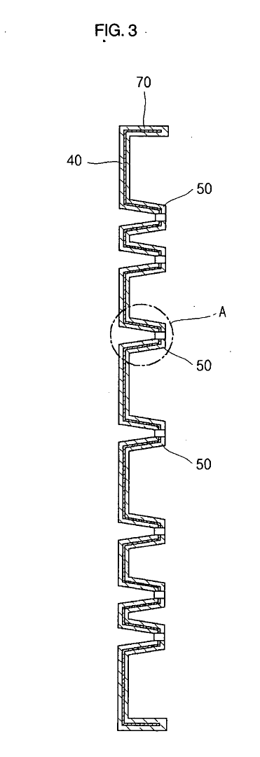

In one embodiment, the chassis base 40 is made of synthetic resin using an injection molding method. In one embodiment, the synthetic resin is selected from at least one of the following: polyester, polycarbonate, and epoxy resins. In another embodiment, the chassis base 40 may be made of other lightweight non-conductive material such as plastic. In one embodiment, during the injection molding of the chassis base 40, the synthetic resin is injection-molded to enclose a grounding member 70 made of metal material or other conductive material (either known or to be developed in the future), so that the chassis base 40 encloses the grounding member 70 as shown in FIGS. 2 and 3.

FIG. 3 is a sectional view showing a chassis base 40 of the plasma display apparatus according to an embodiment of the present invention. In one embodiment, the chassis base 40 has a plurality of bosses 50 integrally formed with the chassis base 40 to protrude and correspond to a mounting position of the circuit board 62. In one embodiment, the chassis base 40 is injection-molded to cover or enclose the grounding member 70.

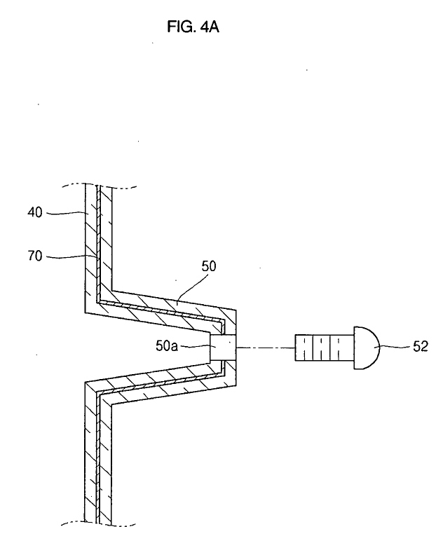

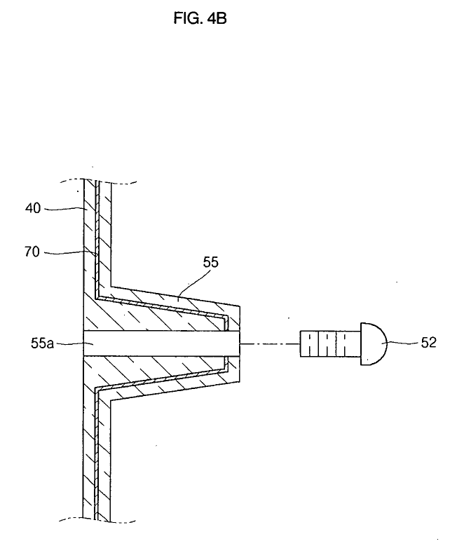

FIG. 4A is an enlarged sectional view showing the chassis base of the plasma display apparatus according to one embodiment of the present invention, marked with dotted circle A in FIG. 3. In one embodiment, the bosses 50, integrated with the chassis base 40, have an inverted U shape in section, i.e., conical-cylinder shape, each of which has a space defined therein. In one embodiment, each boss 50 has a tab hole 50a perforated through a center portion thereof, through which a coupling member such as a bolt 52 extends and is coupled to each boss 50. In this embodiment, the grounding member 70 inserted in the chassis base 40 also extends into the bosses 50.

FIG. 4B is an enlarged sectional view showing a chassis base of the plasma display apparatus according to another embodiment of the present invention, in which a portion corresponds to that marked with the dotted circle A in FIG. 3. In one embodiment, the bosses 50 formed on the chassis base 40 has a trapezoid shape in section, each of which has a tab hole 55a perforated through a center portion of each boss 55a as shown in FIG. 4B.

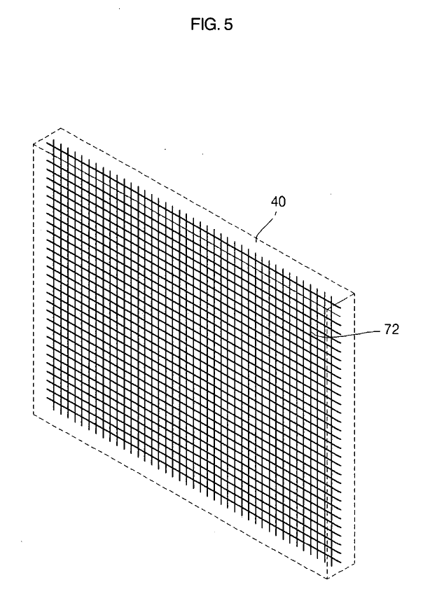

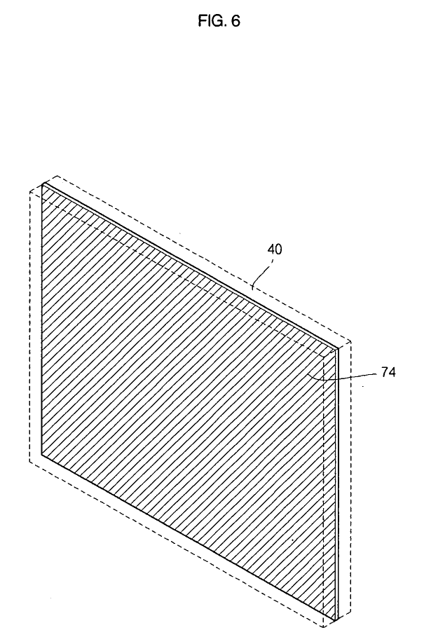

In one embodiment, the grounding member 70 may be formed as a mesh 72 as shown in FIG. 5, or as a thin plate 74 as shown in FIG. 6.

In one embodiment, in the method for injection-molding the chassis base 40, after upper and lower dies are joined together, the synthetic resin is injected into a space between the upper and lower dies so as to form the chassis base 40. I n one embodiment, the grounding member 70 made of the metal mesh or the thin metal plate is inserted between the upper and lower dies before the upper and lower dies are joined together. Then, the synthetic resin is injected into the space between the upper and lower dies. In one embodiment, the grounding member 70 is made of copper or aluminum.

Next, the chassis base 40 has protruding bosses 50 and 55 integrated therewith in order to mount the circuit boards 62 on the chassis base 40. The bosses 50 and 55 have tab holes 50a and 55a perforated therein, respectively.

In one embodiment, the grounding member 70 inserted into the chassis base 40 is in electric contact with the bolt 52, while the bolt 52 is in electric contact with a grounded portion (not shown) of the circuit board 62 fixed to the chassis base 40 by the bolt 52, as shown in FIG. 2. Thus, it can ground the circuit board 62.

According to one embodiment of the present invention as described above, since a part of the chassis base is manufactured by using synthetic resin such as polyester, polycarbonate, or epoxy resin, the manufacturing cost of the chassis base can be significantly reduced in comparison with the manufacturing cost of a chassis base made of solely metal material such as aluminum.

In one embodiment, since the synthetic resin used for making the chassis base, such as polyester, polycarbonate, or epoxy resin, is lighter than that of the existing metal material, there is an advantage in that a total weight of the plasma display apparatus can be reduced.

In another embodiment, the grounding member inserted in the chassis base comes in electric contact with the circuit board which is coupled to the rear surface of the chassis base by the bolts. Thus, the circuit board can be properly grounded.

While the above description has pointed out novel features of the invention as applied to various embodiments, the skilled person will understand that various omissions, substitutions, and changes in the form and details of the device or process illustrated may be made without departing from the scope of the invention. Therefore, the scope of the invention is defined by the appended claims rather than by the foregoing description. All variations coming within the meaning and range of equivalency of the claims are embraced within their scope.

What is claimed is:

1. A plasma display apparatus, comprising:
a plasma display panel including a first panel and a second panel opposing each other, wherein an image is configured to be displayed on the first panel;
a chassis base directly or indirectly coupled to the second panel so as to support the plasma display panel; and
a plurality of circuit boards located on the chassis base,
wherein the chassis base includes i) a body made of synthetic resin and ii) a grounding member enclosed by the body and configured to ground the plurality of circuit boards, and wherein the chassis base further includes bosses configured to couple the plurality of circuit boards to the chassis base.

2. The plasma display apparatus as claimed in claim 1, wherein the bosses have a trapezoid shape in section, and wherein each boss defines a hole through which coupling member extends to fix the circuit boards to the chassis base.

3. The plasma display apparatus as claimed in claim 1, wherein the bosses have an inverted U shaped section, and wherein each boss defines a hole through which a coupling member extends to fix the circuit boards to the chassis base.

4. The plasma display apparatus as claimed in claim 2, wherein a part of the grounding member is exposed within an inner peripheral surface of the hole so as to be in electric contact with the circuit boards through the coupling member.

5. The plasma display apparatus as claimed in claim 1, wherein the grounding member is made of copper or aluminum.

6. The plasma display apparatus as claimed in claim 1, wherein the grounding member is formed in a mesh pattern.

7. The plasma display apparatus as claimed in claim 1, wherein the grounding member is formed as a thin plate.

8. The plasma display apparatus as claimed in claim 1, wherein the synthetic resin is selected from at least one of the following: polyester resin, polycarbonate resin, and epoxy resin.

9. A plasma display apparatus, comprising:
a chassis base, having two opposing surfaces, configured to support a plasma display panel in one surface; and
a plurality of circuit boards located on the other surface of the chassis base and configured to drive the plasma display panel,
wherein the chassis base includes i) a body formed from a non-conductive material and ii) a grounding member formed from a conductive material and configured to ground at least one of the plurality of circuit boards, and wherein the body encloses the grounding member.

10. The plasma display apparatus as claimed in claim 9, wherein the non-conductive material is lighter in weight than the conductive material.

11. The plasma display apparatus as claimed in claim 9, wherein the non-conductive material is synthetic resin or plastic.

12. The plasma display apparatus as claimed in claim 9, wherein the conductive material is copper or aluminum.

13. The plasma display apparatus as claimed in claim 9, further comprising at least one boss configured to couple at least one of the plurality of circuit boards to the chassis base, wherein the at least one boss is integrally formed with the chassis base.

14. The plasma display apparatus as claimed in claim 13, wherein the at least one boss has a trapezoid shape in cross section.

15. The plasma display apparatus as claimed in claim 14, wherein the at least one boss defines a hole through which a coupling member extends to fix at least one of the plurality of circuit boards to the chassis base.

16. A plasma display apparatus, comprising:
a chassis base, having two opposing surfaces, configured to support a plasma display panel in one surface and at least one circuit board in the other surface,
wherein the chassis base includes i) a body formed from synthetic resin and ii) a grounding member formed from metal and configured to ground the at least one circuit board, and wherein the body encloses the grounding member.

17. The plasma display apparatus as claimed in claim 16, wherein the synthetic resin is selected from at least one of the following: polyester resin, polycarbonate resin, and epoxy resin.

18. The plasma display apparatus as claimed in claim 16, wherein the grounding member is formed in a mesh pattern or as a thin plate.

19. The plasma display apparatus as claimed in claim 16, further comprising at least one boss configured to couple the at least one circuit board to the chassis base, wherein the at least one boss is integrally formed with the chassis base.

20. The plasma display apparatus as claimed in claim 19, wherein the at least one boss has an inverted U shaped section and defines a hole through which a coupling member extends to fix the at least one circuit board to the chassis base.
